(19) United States
(12) Patent Application Publication
(10) Pub. No.: US 2026/0066790 A1
(43) Pub. Date: Mar. 5, 2026

(54) SWITCHING VOLTAGE GENERATING DEVICE AND VOLTAGE CONVERTING DEVICE INCLUDING THE SAME

(71) Applicant: Samsung Electronics Co., Ltd., Suwon-si (KR)

(72) Inventors: Woojin Hong, Suwon-si (KR); Sungwoo Lee, Suwon-si (KR); Woonhyung Heo, Suwon-si (KR)

(21) Appl. No.: 19/301,660

(22) Filed: Aug. 15, 2025

(30) Foreign Application Priority Data
Aug. 27, 2024 (KR) 10-2024-0115257
Feb. 14, 2025 (KR) 10-2025-0019630

(51) Int. Cl. H02M 3/158; H02J 7/00; H03F 3/45; H03K 4/06

(52) U.S. Cl. CPC H02M 3/158; H02J 7/933; H03K 4/06; H02J 2207/20; H03F 3/45475

(57) ABSTRACT

A switching voltage generating device includes an amplifier configured to generate an error voltage, based on a adjusting target voltage of the voltage converting circuit and a detection voltage of the voltage converting circuit, a clock voltage generating circuit configured to generate a clock voltage having a frequency corresponding to the error voltage, based on the error voltage, a first fold reference voltage, and a second fold reference voltage, and to generate a clock switching voltage based on the error voltage and the switching reference voltage, a triangular voltage generating circuit configured to generate one or more triangular voltages having a cycle corresponding to a cycle of the clock voltage based on the clock switching voltage and the clock voltage, and a switching voltage generating circuit configured to generate the switching voltage based on the one or more triangular voltages and the error voltage.

### CROSS-REFERENCE TO RELATED APPLICATIONS

This application is based on and claims priority under 35 U.S. C. § 119 to Korean Patent Application Nos. 10-2024-0115257 filed on Aug. 27, 2024 and 10-2025-0019630 filed on Feb. 14, 2025, in the Korean Intellectual Property Office, the disclosure of each of which is incorporated by reference herein in its entirety.

### BACKGROUND

The inventive concept relates to a switching voltage generating device generating a switching voltage applied to a switching element included in a voltage converting device.

A voltage converting device may convert the magnitude of an input voltage and may output an output voltage having a magnitude required by another device. The voltage converting device may include one or more switching elements, and may generate an output voltage of a desired magnitude by turning the one or more switching elements on or off.

The voltage converting device may control the magnitude of the output voltage by controlling a duty ratio that is a ratio of the time that one or more switching elements are turned on in a cycle. When the duty ratio varies over a wider range, a range of an output voltage that may be generated by the voltage converting device may also be wider.

### SUMMARY

The inventive concept relates to a switching voltage generating device generating a switching voltage having a wide range of duty ratio.

According to an aspect of the inventive concept, a switching voltage generating device generating one or more switching voltages input to one or more switching elements included in a voltage converting circuit includes an amplifier configured to generate an error voltage, based on a adjusting target voltage of the voltage converting circuit and a detection voltage of the voltage converting circuit, a clock voltage generating circuit configured to generate a clock voltage having a frequency corresponding to the error voltage, based on the error voltage, a first fold reference voltage, and a second fold reference voltage, and to generate a clock switching voltage based on the error voltage and a switching reference voltage, a triangular voltage generating circuit configured to generate one or more triangular voltages having a cycle corresponding to a cycle of the clock voltage based on the clock switching voltage and the clock voltage, and a switching voltage generating circuit configured to generate the one or more switching voltages based on the one or more triangular voltages and the error voltage.

According to another aspect of the inventive concept, a voltage converting device includes a voltage converting circuit configured to convert an input voltage to generate a system voltage and a switching voltage generating device configured to generate one or more switching voltages input to one or more switching elements included in the voltage converting circuit. The switching voltage generating device includes an amplifier configured to generate an error voltage, based on a adjusting target voltage of the voltage converting circuit and a detection voltage of the voltage converting circuit, a clock voltage generating circuit configured to generate a clock voltage having a frequency corresponding to the error voltage, based on the error voltage, a first fold reference voltage, and a second fold reference voltage, and to generate a clock switching voltage based on the error voltage and a switching reference voltage, a triangular voltage generating circuit configured to generate one or more triangular voltages having a cycle corresponding to a cycle of the clock voltage based on the clock switching voltage and the clock voltage, and a switching voltage generating circuit configured to generate the one or more switching voltages based on the one or more triangular voltages and the error voltage.

According to another aspect of the inventive concept, there is provided a switching voltage generating device generating a switching voltage input to a switching element included in a voltage converting circuit, including an amplifier configured to generate an error voltage, based on a adjusting target voltage of the voltage converting circuit and a detection voltage of the voltage converting circuit, a clock voltage generating circuit configured to generate a clock voltage having a frequency corresponding to the error voltage, a triangular voltage generating circuit configured to generate one or more triangular voltages having a cycle corresponding to a cycle of the clock voltage, and a switching voltage generating circuit configured to generate the switching voltage based on the one or more triangular voltages and the error voltage.

### BRIEF DESCRIPTION OF THE DRAWINGS

Embodiments will be more clearly understood from the following detailed description taken in conjunction with the accompanying drawings in which:

FIG. 1 is a block diagram illustrating a voltage converting device including a switching voltage generating device according to an embodiment;

FIG. 2 is a diagram illustrating an example of a voltage converting circuit included in a voltage converting device according to an embodiment;

FIG. 3 is a diagram illustrating a loop selecting circuit included in a voltage converting device according to an embodiment;

FIG. 4 is a diagram illustrating a switching voltage generating device according to an embodiment;

FIG. 5 is a diagram illustrating a clock voltage generating circuit included in a switching voltage generating device according to an embodiment;

FIG. 6 is a diagram illustrating a triangular voltage generating circuit included in a switching voltage generating device according to an embodiment;

FIG. 7 is a diagram illustrating a portion of a first triangular voltage generator included in a switching voltage generating device according to an embodiment;

FIG. 8 is a diagram illustrating the remaining portion of a first triangular voltage generator included in a switching voltage generating device according to an embodiment;

FIG. 9 is a diagram illustrating a switching voltage generating circuit included in a switching voltage generating device according to an embodiment;

FIG. 10 is a graph illustrating a relationship between an error voltage of a switching voltage generating device and a frequency of a clock voltage according to an embodiment;

FIG. 11 is a timing diagram illustrating a relationship between voltages generated by a switching voltage generating device according to an embodiment; and

FIG. 12 is a timing diagram illustrating a relationship between voltages generated by a first triangular voltage generator of a switching voltage generating device according to an embodiment.

### DETAILED DESCRIPTION OF THE EMBODIMENTS

Hereinafter, embodiments of the inventive concept will be described in detail with reference to the accompanying drawings.

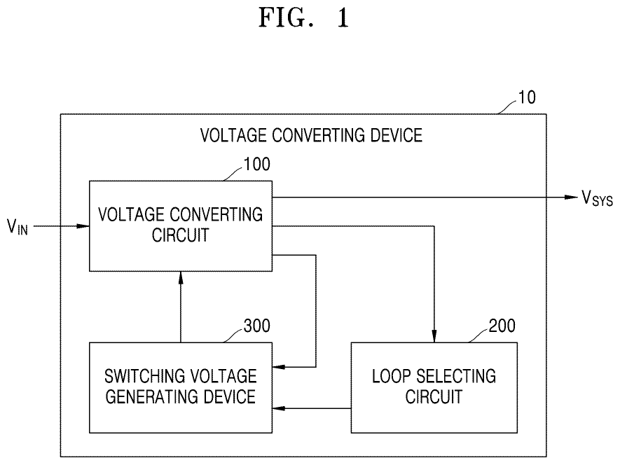

FIG. 1 is a block diagram illustrating a voltage converting device 10 including a switching voltage generating device 300 according to an embodiment.

Referring to FIG. 1, the voltage converting device 10 according to an embodiment may include a voltage converting circuit 100, a loop selecting circuit 200, and the switching voltage generating device 300.

The voltage converting device 10 may receive an input voltage V_{IN}. The voltage converting device 10 may generate a system voltage V_{SYS} based on the input voltage V_{IN}. The system voltage V_{SYS} may be required for operation in a device including the voltage converting device 10 or in another device in a system.

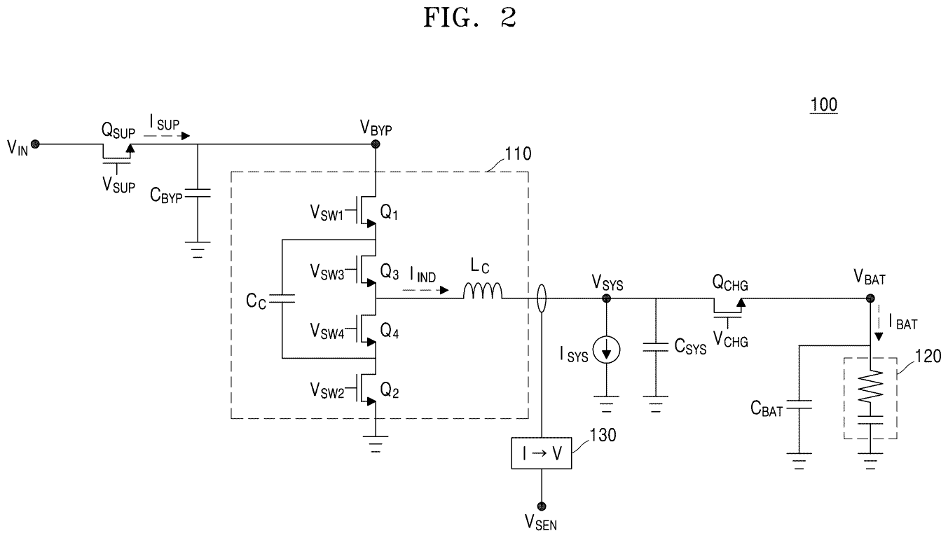

The voltage converting circuit 100 may convert the input voltage V_{IN} to generate the system voltage V_{SYS}. The voltage converting circuit 100 may include one or more switching elements, and may generate the system voltage V_{SYS} of a magnitude different from that of the input voltage V_{IN} as one or more switching elements are turned on or off. The one or more switching elements included in the voltage converting circuit 100 may be turned on or off based on a switching voltage generated by the switching voltage generating device 300. An example of the voltage converting circuit 100 will be described below with reference to FIG. 2.

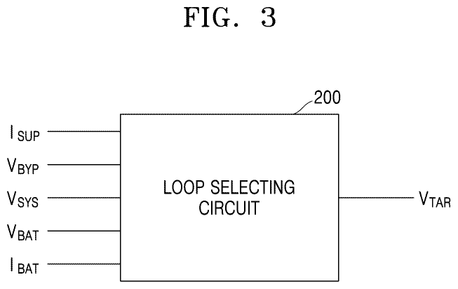

The loop selecting circuit 200 may determine an adjusting target voltage. The loop selecting circuit 200 may determine the adjusting target voltage based on a voltage and current in the voltage converting circuit 100. A target to be adjusted among the voltage and current in the voltage converting circuit 100 may be selected through the loop selecting circuit 200. An example of the loop selecting circuit 200 will be described below with reference to FIG. 3.

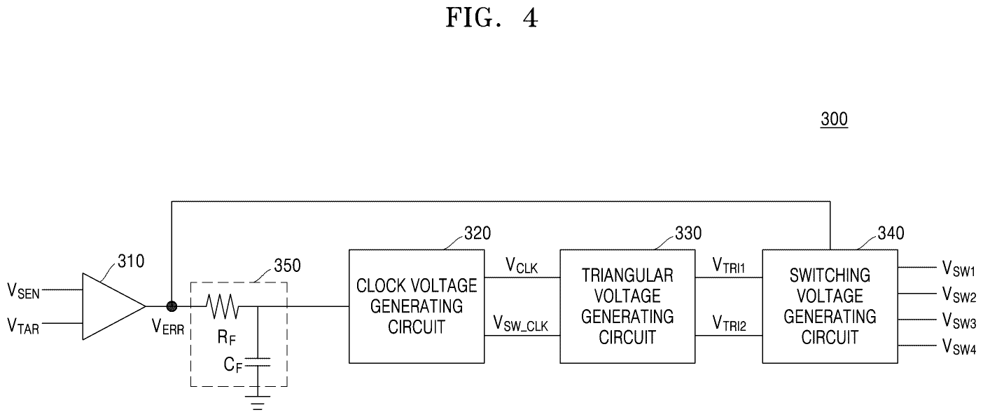

The switching voltage generating device 300 may generate the switching voltage input to the one or more switching elements included in the voltage converting circuit 100. In an embodiment, the switching voltage generating device 300 may generate an error voltage, based on the adjusting target voltage of the voltage converting circuit 100 and a detection voltage of the voltage converting circuit 100, may generate a clock voltage having a frequency corresponding to the error voltage, and may generate the switching voltage based on the clock voltage. By varying the frequency of the clock voltage according to the error voltage in this way, the switching voltage having a wide range of duty ratio may be generated. A more specific structure and operation of the switching voltage generating device 300 will be described later with reference to FIG. 4 and below.

FIG. 2 is a diagram illustrating an example of a voltage converting circuit 100 included in a voltage converting device according to an embodiment.

Referring to FIG. 2, the voltage converting circuit 100 according to an embodiment may include a supply switching element Q_{SUP}, a bypass capacitor C_{BYP}, a DC-DC converter 110, a system current source I_{SYS}, a system capacitor C_{SYS}, a charge switching element Q_{CHG}, a battery 120, a battery capacitor C_{BAT}, and a current-to-voltage converter 130.

The supply switching element Q_{SUP} may control supply of the input voltage V_{IN}. The supply switching element Q_{SUP} may receive the input voltage V_{IN}. The supply switching element Q_{SUP} may receive the input voltage V_{IN} through one end (for example, a drain stage) of the supply switching element Q_{SUP.}

The supply switching element Q_{SUP} may be turned on or off based on the supply voltage V_{SUP} applied through an input stage (for example, a gate stage) of the supply switching element Q_{SUP}. The supply voltage V_{SUP} may be applied to the input stage of the supply switching element Q_{SUP} through a controller (not shown) included in the voltage converting device 10. The controller may turn the supply switching element Q_{SUP} on or off by controlling the supply voltage V_{SUP} considering whether the voltage converting device 10 is abnormal or not.

The supply switching element Q_{SUP} may be connected to the bypass capacitor C_{BYP} and the DC-DC converter 110 through the other end (for example, a source stage). When the supply switching element Q_{SUP} is turned on, the supply current I_{SUP} may be transmitted to the bypass capacitor C_{BYP} and the DC-DC converter 110 through the supply switching element Q_{SUP}, through which the input voltage V_{IN} may be supplied to other components of the voltage converting circuit 100. Conversely, when the supply switching element Q_{SUP} is turned off, the supply current I_{SUP} may not be transmitted to the bypass capacitor C_{BYP} and the DC-DC converter 110 through the supply switching element Q_{SUP}.

The bypass capacitor C_{BYP} may be connected between the supply switching element Q_{SUP} and a ground voltage stage. The bypass capacitor C_{BYP} may be connected to the other end of the supply switching element Q_{SUP} through one end. The bypass capacitor C_{BYP} may be connected to the ground voltage stage through the other end. The bypass capacitor C_{BYP} may smooth the input voltage V_{IN}, and thus, the bypass voltage V_{BYP} with the smoothed input voltage V_{IN} can be provided to the DC-DC converter 110.

The DC-DC converter 110 may be connected between the supply switching element Q_{SUP} and the ground voltage stage. The DC-DC converter 110 may output the system voltage V_{SYS} by controlling the magnitude of the bypass voltage V_{BYP}. Although the DC-DC converter 110 is illustrated as being a 3-level buck converter in the embodiment of FIG. 2, the inventive concept is not limited thereto. Unlike in the embodiment of FIG. 2, other types of converters capable of controlling the magnitude of a voltage by using one or more switching elements may be used as the DC-DC converter 110. However, for convenience of explanation, the following description will focus on an embodiment in which the DC-DC converter 110 is the 3-level buck converter.

The DC-DC converter 110 may include first to fourth switching elements Q₁ to Q₄, a conversion capacitor C_{C}, and a conversion inductor L_{C}.

The first switching element Q₁ may receive the bypass voltage V_{BYP} through one end (for example, a drain stage) of the first switching element Q₁. The first switching element Q₁ may be turned on or off based on a first switching voltage V_{SW1} applied through an input stage (for example, a gate stage) of the first switching element Q₁. The other end (for example, a source stage) of the first switching element Q₁ may be connected to one end (for example, a drain stage) of the third switching element Q₃.

The third switching element Q₃ may be connected to the other end of the first switching element Q₁ through one end. The third switching element Q₃ may be turned on or off based on a third switching voltage V_{SW3} applied through an input stage (for example, a gate stage) of the third switching element Q₃. The other end (for example, a source stage) of the third switching element Q₃ may be connected to one end (for example, a drain stage) of the fourth switching element Q₄.

The fourth switching element Q₄ may be connected to the other end of the third switching element Q₃ through one end. The fourth switching element Q₄ may be turned on or off based on a fourth switching voltage V_{SW4} applied through an input stage (for example, a gate stage) of the fourth switching element Q₄. The other end (for example, a source stage) of the fourth switching element Q₄ may be connected to one end (for example, a drain stage) of the second switching element Q₂.

The second switching element Q₂ may be connected to the other end of the fourth switching element Q₄ through one end. The second switching element Q₂ may be turned on or off based on a second switching voltage V_{SW2} applied through an input stage (for example, a gate stage) of the second switching element Q₂. The other end (for example, a source stage) of the second switching element Q₂ may be connected to the ground voltage stage.

The conversion capacitor C_{C} may be connected between the other end of the first switching element Q₁ and one end of the third switching element Q₃ through one end of the conversion capacitor C_{C}. The conversion capacitor C_{C} may be connected between the other end of the fourth switching element Q₄ and one end of the second switching element Q₂ through the other end of the conversion capacitor C_{C}.

The conversion inductor L_{C} may be connected between the other end of the third switching element Q₃ and one end of the fourth switching element Q₄ through one end of the conversion inductor L_{C}. The conversion inductor L_{C} may output the system voltage V_{SYS} through the other end of the conversion inductor L_{C}.

The first to fourth switching elements Q₁ to Q₄, the conversion capacitor C_{C}, and the conversion inductor L_{C} connected in this manner may generate the system voltage V_{SYS} as the first to fourth switching elements Q₁ to Q₄ are turned on or off based on the first to fourth switching voltages V_{SW1} to V_{SW4} received from the switching voltage generating device 300.

The system current source I_{SYS} may be connected between a system voltage V_{SYS} stage and the ground voltage stage. The system capacitor C_{SYS} may be connected between the system voltage V_{SYS} stage and the ground voltage stage.

The charge switching element Q_{CHG} may control connection between the system voltage V_{SYS} stage and the battery 120. The charge switching element Q_{CHG} may control the charging of the battery 120 through the system voltage V_{SYS}. The charge switching element Q_{CHG} may receive the system voltage V_{SYS}. The charge switching element Q_{CHG} may receive the system voltage V_{SYS} through one end (for example, a drain stage) of the charge switching element Q_{CHG.}

The charge switching element Q_{CHG} may be turned on or off based on a charging voltage V_{CHG} applied through an input stage (for example a gate stage) of the charge switching element Q_{CHG}. The charging voltage V_{CHG} may be applied to the input stage of the charge switching element Q_{CHG} through the controller (not shown) included in the voltage converting device 10. The controller may turn on or off the charge switching element Q_{CHG} by controlling the charging voltage V_{CHG} according to whether to charge the battery 120.

The charge switching element Q_{CHG} may be connected to the battery capacitor C_{BAT} and the battery 120 through the other end (for example, a source stage) of the charge switching element Q_{CHG}. When the charge switching element Q_{CHG} is turned on, a battery current I_{BAT} may be transmitted to the battery capacitor C_{BAT} and the battery 120 through the charge switching element Q_{CHG}, and thus the battery 120 may be charged. Conversely, when the charge switching element Q_{CHG} is turned off, the battery current I_{BAT} may not be transmitted to the battery capacitor C_{BAT} and the battery 120 through the charge switching element Q_{CHG}.

The battery 120 may store power. The battery 120 may include one or more resistors and one or more capacitors. The battery 120 may be connected between a battery voltage V_{BAT} that is the other end of the charge switching element Q_{CHG} and the ground voltage stage.

The battery capacitor C_{BAT} may be connected between one end of the battery 120 and the ground voltage stage. The battery capacitor C_{BAT} may smooth the battery voltage V_{BAT}, and thus, the battery voltage V_{BAT} may be stably charged in the battery 120.

The current-to-voltage converter 130 may output a detection voltage V_{SEN} based on current output from the DC-DC converter 110. The current-to-voltage converter 130 may output the detection voltage V_{SEN} corresponding to an inductor current I_{IND} flowing through the conversion inductor L_{C}.

FIG. 3 is a diagram illustrating a loop selecting circuit 200 included in the voltage converting device 10 according to an embodiment.

Referring to FIG. 3, the loop selecting circuit 200 according to an embodiment may determine a adjusting target voltage V_{TAR} based on the supply current I_{SUP}, the bypass voltage V_{BYP}, the system voltage V_{SYS}, the battery voltage V_{BAT}, and the battery current I_{BAT}.

The loop selecting circuit 200 may determine a voltage corresponding to one of the supply current I_{SUP} passing through the supply switching element Q_{SUP}, the bypass voltage V_{BYP} between the bypass capacitor C_{BYP} and the DC-DC converter 110, the system voltage V_{SYS}, the battery voltage V_{BAT} between the charge switching element Q_{CHG} and the battery 120, and the battery current I_{BAT} supplied to the battery 120 as the adjusting target voltage V_{TAR}.

The loop selecting circuit 200 may determine a voltage corresponding to one of the supply current I_{SUP}, the bypass voltage V_{BYP}, the system voltage V_{SYS}, the battery voltage V_{BAT}, and the battery current I_{BAT} as the adjusting target voltage V_{TAR} considering the current operating state of the voltage converting device 10.

In an example embodiment, the voltage converting circuit 100 may include the loop selecting circuit 200.

FIG. 4 is a diagram illustrating the switching voltage generating device 300 according to an embodiment.

Referring to FIG. 4, the switching voltage generating device 300 according to an embodiment may include an amplifier 310, a clock voltage generating circuit 320, a triangular voltage generating circuit 330, and a switching voltage generating circuit 340.

The amplifier 310 may generate an error voltage V_{ERR} based on the adjusting target voltage V_{TAR} of the voltage converting circuit 100 determined by the loop selecting circuit 200 and the detection voltage V_{SEN} of the voltage converting circuit 100. The amplifier 310 may amplify the difference between the adjusting target voltage V_{TAR} and the detection voltage V_{SEN} to generate the error voltage V_{ERR}.

The switching voltage generating device 300 may further include a filter circuit 350. The filter circuit 350 may include a filter resistor R_{F} and a filter capacitor C_{F}. The filter resistor R_{F} may be connected to the amplifier 310 through one end of the filter resistor R_{F}. The filter resistor R_{F} may be connected to the clock voltage generating circuit 320 through the other end of the filter resistor R_{F}. The filter capacitor C_{F} may be connected to the other end of the filter resistor R_{F} through one end of the filter capacitor C_{F}. The filter capacitor C_{F} may be connected to the ground voltage stage through the other end of the filter capacitor C_{F}. The filter circuit 350 may operate as a low pass filter (LPF) to filter out high-frequency components included in the error voltage V_{ERR}.

The clock voltage generating circuit 320 may generate the clock voltage V_{CLK} based on the error voltage V_{ERR}. The clock voltage generating circuit 320 may generate the clock voltage V_{CLK} having a frequency corresponding to the error voltage V_{ERR}, based on the error voltage V_{ERR}, a first fold reference voltage V_{FOLD_REF1}, and a second fold reference voltage V_{FOLD_REF2}.

In addition, the clock voltage generating circuit 320 may generate a clock switching voltage V_{SW_CLK} based on the error voltage V_{ERR}. The clock voltage generating circuit 320 may generate the clock switching voltage V_{SW_CLK}, based on the error voltage V_{ERR} and a switching reference voltage V_{SW_REF}.

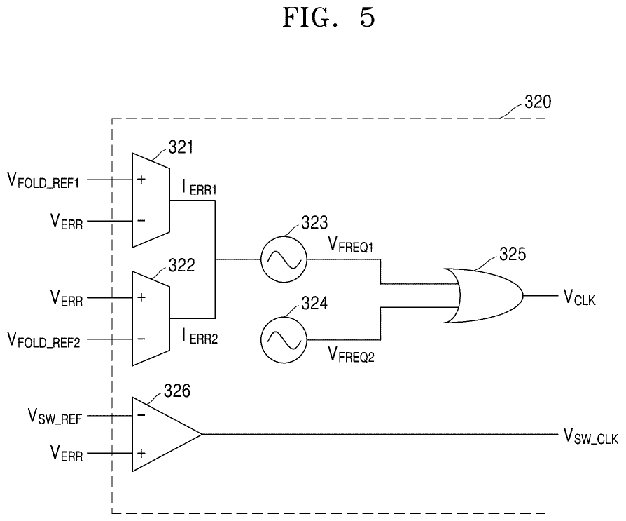

A more specific structure and operation of the clock voltage generating circuit 320 may be described in more detail with reference to FIG. 5.

FIG. 5 is a diagram illustrating the clock voltage generating circuit 320 included in the switching voltage generating device 300 according to an embodiment.

Referring to FIG. 5, the clock voltage generating circuit 320 according to an embodiment may include a first operational transconductance amplifier (OTA) 321, a second OTA 322, a first oscillator 323, a second oscillator 324, a logic element 325, and a switching comparator 326.

The first OTA 321 may receive the error voltage V_{ERR} and the first fold reference voltage V_{FOLD_REF1}. The first OTA 321 may output a first error current I_{ERR1} corresponding to a difference between the error voltage V_{ERR} and the first fold reference voltage V_{FOLD_REF1}. The first fold reference voltage V_{FOLD_REF1} may be at a lower voltage level of the error voltage V_{ERR} determining whether to reduce the frequency of the clock voltage V_{CLK}, and for example, the first fold reference voltage V_{FOLD_REF1} may be 0.9 V.

For example, when the result of subtracting the error voltage V_{ERR} from the first fold reference voltage V_{FOLD_REF1} is positive, the first OTA 321 may output the first error current I_{ERR1} having a magnitude proportional to the difference between the error voltage V_{ERR} and the first fold reference voltage V_{FOLD_REF1}. Conversely, when the result of subtracting the error voltage V_{ERR} from the first fold reference voltage V_{FOLD_REF1} is negative or 0, the first OTA 321 may output the first error current I_{ERR1} having a magnitude of 0 A.

The second OTA 322 may receive the error voltage V_{ERR} and the second fold reference voltage V_{FOLD_REF2}. The second OTA 322 may output a second error current I_{ERR2} corresponding to a difference between the error voltage V_{ERR} and the second fold reference voltage V_{FOLD_REF2}. The second fold reference voltage V_{FOLD_REF2} may be at an upper voltage level of the error voltage V_{ERR} determining whether to reduce the frequency of the clock voltage V_{CLK}, and for example, the second fold reference voltage V_{FOLD_REF2} may be 0.9 V.

For example, when the result of subtracting the second fold reference voltage V_{FOLD_REF2} from the error voltage V_{ERR} is positive, the first OTA 321 may output the second error current I_{ERR2} having a magnitude proportional to the difference between the error voltage V_{ERR} and the second fold reference voltage V_{FOLD_REF2}. Conversely, when the result of subtracting the second fold reference voltage V_{FOLD_REF2} from the error voltage V_{ERR} is negative or 0, the second OTA 322 may output the second error current I_{ERR2} having a magnitude of 0 A.

The first oscillator 323 may receive the first error current I_{ERR1} and the second error current I_{ERR2}. At this time, the first oscillator 323 may receive a current obtained by adding the first error current I_{ERR1} to the second error current I_{ERR2}.

The first oscillator 323 may output a first frequency voltage V_{FREQ1} having a frequency inversely proportional to the first error current I_{ERR1} and the second error current I_{ERR2}. For example, the first oscillator 323 may output the first frequency voltage V_{FREQ1} having a maximum limit frequency of the clock voltage V_{CLK} when the current obtained by adding the first error current I_{ERR1} to the second error current I_{ERR2} is 0 A. In addition, the first oscillator 323 may output the first frequency voltage V_{FREQ1} having a frequency less than the maximum limit frequency by an amount inversely proportional to the magnitude of the current obtained by adding the first error current I_{ERR1} to the second error current I_{ERR2} when the current obtained by adding the first error current I_{ERR1} to the second error current I_{ERR2} is greater than 0 A.

The second oscillator 324 may output a second frequency voltage V_{FREQ2} having a frequency corresponding to a minimum limit frequency of the clock voltage V_{CLK}. For example, the minimum limit frequency may be ¼ of the maximum limit frequency. The second oscillator 324 may always output the second frequency voltage V_{FREQ2}.

The logic element 325 may output a voltage having a higher frequency among the first frequency voltage V_{FREQ1} and the second frequency voltage V_{FREQ2} as the clock voltage V_{CLK}. For example, the logic element 325 may include an OR gate.

When the current obtained by adding the first error current I_{ERR1} to the second error current I_{ERR2} is 0 A, because the first frequency voltage V_{FREQ1} has the maximum limit frequency, and the second frequency voltage V_{FREQ2} has a minimum limit frequency, the logic element 325 may output the first frequency voltage V_{FREQ1} as the clock voltage V_{CLK}. At this time, when the current obtained by adding the first error current I_{ERR1} to the second error current I_{ERR2} increases, the logic element 325 outputs the first frequency voltage V_{FREQ1} having a gradually decreasing frequency, and when the first frequency voltage V_{FREQ1} begins to have a frequency of the minimum limit frequency or less, the logic element 325 may output the second frequency voltage V_{FREQ2}.

When the frequency of the first frequency voltage V_{FREQ1} is less than the frequency of the second frequency voltage V_{FREQ2}, the logic element 325 may output the second frequency voltage V_{FREQ2}. At this time, when the current obtained by adding the first error current I_{ERR1} to the second error current I_{ERR2} increases, the logic element 325 outputs the second frequency voltage V_{FREQ2}, and when the first frequency voltage V_{FREQ1} begins to have a frequency of the minimum limit frequency or more, the logic element 325 may output the first frequency voltage V_{FREQ1}.

The switching comparator 326 may receive the error voltage V_{ERR} and the switching reference voltage V_{SW_REF}. The switching comparator 326 may compare the error voltage V_{ERR} with the switching reference voltage V_{SW_REF} to generate the clock switching voltage V_{SW_CLK}. The switching reference voltage V_{SW_REF} may be at a level serving as a reference for determining whether to further increase or further decrease a duty ratio of the switching voltage according to the magnitude of the error voltage V_{ERR}. For example, the switching reference voltage V_{SW_REF} may be 1.5 V.

The switching comparator 326 may generate the clock switching voltage V_{SW_CLK} corresponding to a value of logic 0 when the error voltage V_{ERR} is greater than the switching reference voltage V_{SW_REF}. Conversely, the switching comparator 326 may generate the clock switching voltage V_{SW_CLK} corresponding to a value of logic 1 when the error voltage V_{ERR} is less than the switching reference voltage V_{SW_REF}.

Returning to FIG. 4 again, the triangular voltage generating circuit 330 may generate one or more triangular voltages based on the clock voltage V_{CLK}. In the embodiment of FIG. 4, in order to generate a switching voltage applied to the DC-DC converter 110 of FIG. 2, the triangular voltage generating circuit 330 may generate a first triangular voltage V_{TRI1} and a second triangular voltage V_{TRI2}. Hereinafter, for convenience of explanation, the following description will focus on an embodiment in which the triangular voltage generating circuit 330 generates the first triangular voltage V_{TRI1} and the second triangular voltage V_{TRI2}.

The triangular voltage generating circuit 330 may generate the first triangular voltage V_{TRI1} and the second triangular voltage V_{TRI2} having a cycle corresponding to a cycle of the clock voltage V_{CLK} based on the clock voltage V_{CLK} and the clock switching voltage V_{SW_CLK}.

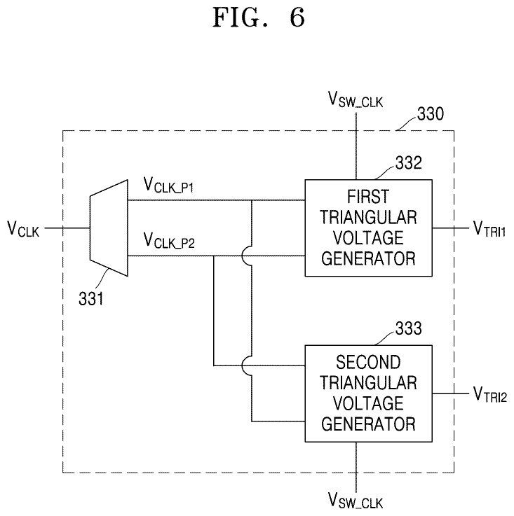

A more specific structure and operation of the triangular voltage generating circuit 330 may be described in more detail with reference to FIG. 6.

FIG. 6 is a diagram illustrating the triangular voltage generating circuit 330 included in the switching voltage generating device 300 according to an embodiment.

Referring to FIG. 6, the triangular voltage generating circuit 330 according to an embodiment may include a demultiplexer 331, a first triangular voltage generator 332, and a second triangular voltage generator 333.

The demultiplexer 331 may generate a first phase clock voltage V_{CLK_P1} and a second phase clock voltage V_{CLK_P2} based on the clock voltage V_{CLK}. The demultiplexer 331 may alternately output the clock voltage V_{CLK} as the first phase clock voltage V_{CLK_P1} and the second phase clock voltage V_{CLK_P2} in response to a rising edge of the clock voltage V_{CLK}. For example, the demultiplexer 331 may output the clock voltage V_{CLK} as the first phase clock voltage V_{CLK_P1} in response to an odd rising edge of the clock voltage V_{CLK}, and may output the clock voltage V_{CLK} as the second phase clock voltage V_{CLK_P2} in response to an even rising edge of the clock voltage V_{CLK}.

The first triangular voltage generator 332 may receive the clock switching voltage V_{SW_CLK}, the first phase clock voltage V_{CLK_P1}, and the second phase clock voltage V_{CLK_P2}. The first triangular voltage generator 332 may generate a first triangular voltage V_{TRI1} based on the clock switching voltage V_{SW_CLK}, the first phase clock voltage V_{CLK_P1}, and the second phase clock voltage V_{CLK_P2.}

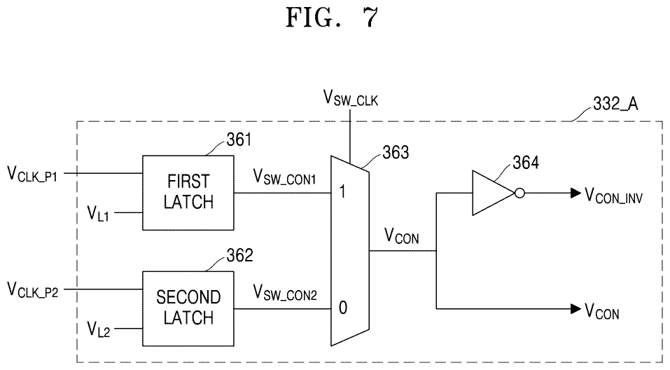

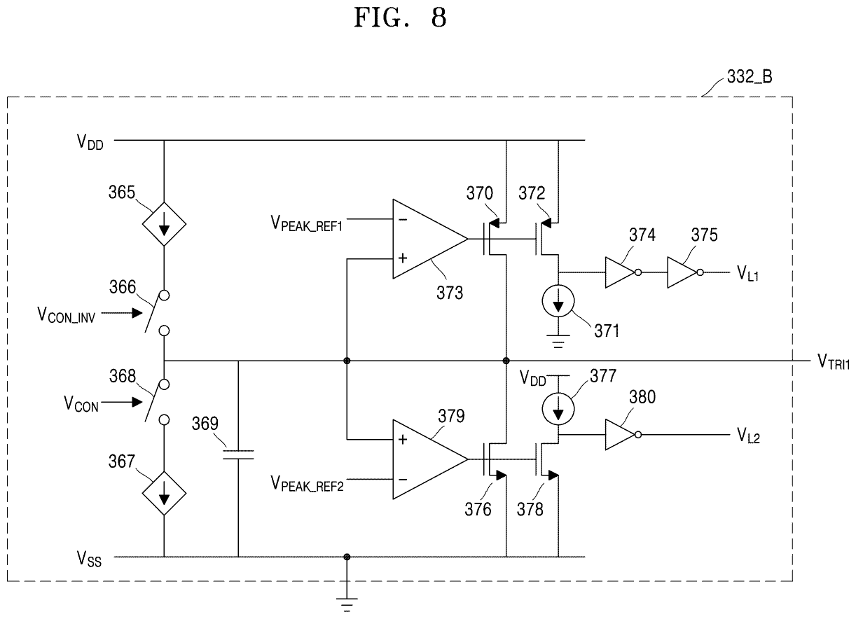

A more specific structure and operation of the first triangular voltage generator 332 may be described in more detail with reference to FIGS. 7 and 8.

FIG. 7 is a diagram illustrating a portion 332_A of the first triangular voltage generator 332 included in the switching voltage generating device 300 according to an embodiment.

Referring to FIG. 7, the portion 332_A of the first triangular voltage generator 332 may include a first latch 361, a second latch 362, a multiplexer 363, and a first inverter 364.

The first latch 361 may receive a first phase clock voltage V_{CLK_P1} and a first logic voltage V_{L1}. The first latch 361 may generate a first switching control voltage V_{SW_CON1} based on the first phase clock voltage V_{CLK_P1} and the first logic voltage V_{L1}.

In an embodiment, the first latch 361 may include an S-R latch. At this time, an S terminal input of the first latch 361 may include the first phase clock voltage V_{CLK_P1}, an R terminal input of the first latch 361 may include the first logic voltage V_{L1}, and a Q terminal output of the first latch 361 may include the first switching control voltage V_{SW_CON1}. Accordingly, the first switching control voltage V_{SW_CON1} may have a value of logic 1 in response to a rising edge of the first phase clock voltage V_{CLK_P1}, and the first switching control voltage V_{SW_CON1} may have a value of logic 0 in response to a rising edge of the first logic voltage V_{L1}.

The second latch 362 may receive the second phase clock voltage V_{CLK_P2} and the second logic voltage V_{L2}. The second latch 362 may generate a second switching control voltage V_{SW_CON2} based on the second phase clock voltage V_{CLK_P2} and the second logic voltage V_{L2}.

In an embodiment, the second latch 362 may include an S-R latch. At this time, an S terminal input of the second latch 362 may include the second phase clock voltage V_{CLK_P2}, an R terminal input of the second latch 362 may include the second logic voltage V_{L2}, and a Q̅ terminal output of the second latch 362 may include the second switching control voltage V_{SW_CON2}. Accordingly, the second switching control voltage V_{SW_CON2} may have a value of logic 0 in response to a rising edge of the second phase clock voltage V_{CLK_P2}, and the second switching control voltage V_{SW_CON2} may have a value of logic 1 in response to a rising edge of the second logic voltage V_{L2}.

The multiplexer 363 may select one of the first switching control voltage V_{SW_CON1} and the second switching control voltage V_{SW_CON2} as a control voltage V_{CON} based on the clock switching voltage V_{SW_CLK}. For example, the multiplexer 363 may output the first switching control voltage V_{SW_CON1} as the control voltage V_{CON} when the clock switching voltage V_{SW_CLK} has a value of logic 1. Conversely, the multiplexer 363 may output the second switching control voltage V_{SW_CON2} as the control voltage V_{CON} when the clock switching voltage V_{SW_CLK} has a value of logic 0.

The first inverter 364 may receive the control voltage V_{CON}. The first inverter 364 may invert the control voltage V_{CON} to output an inverted control voltage V_{CON_INV}.

FIG. 8 is a diagram illustrating the remaining portion 332_B of the first triangular voltage generator included in the switching voltage generating device 300 according to an embodiment.

Referring to FIG. 8, the remaining portion 332_B of the first triangular voltage generator may include a first current source 365, a first connection switching element 366, a second current source 367, a second connection switching element 368, a triangular capacitor 369, a first logic switching element 370, a third current source 371, a second logic switching element 372, a first voltage clamper 373, a second inverter 374, a third inverter 375, a third logic switching element 376, a fourth current source 377, a fourth logic switching element 378, a second voltage clamper 379, and a fourth inverter 380.

The first current source 365 may be connected to a first operating voltage stage V_{DD} through one end of the first current source 365.

The first connection switching element 366 may be connected between the other end of the first current source 365 and the first triangular voltage stage V_{TRI1}. The first connection switching element 366 may be turned on or off by the inverted control voltage V_{CON_INV}.

The second current source 367 may be connected to a second operating voltage stage V_{SS} through one end of the second current source 367. For example, the second operating voltage stage V_{SS} may be a ground voltage stage.

The second connection switching element 368 may be connected between the other end of the second current source 367 and the first triangular voltage stage V_{TRI1}. The second connection switching element 368 may be turned on or off by the control voltage V_{CON}.

The triangular capacitor 369 may be connected to the first triangular voltage stage V_{TRI1} through one end of the triangular capacitor 369. The triangular capacitor 369 may be connected to the second operating voltage stage V_{SS} through the other end of the triangular capacitor 369.

Because the first connection switching element 366 is turned on or off by the inverted control voltage V_{CON_INV}, and the second connection switching element 368 is turned on or off by the control voltage V_{CON}, the first connection switching element 366 and the second connection switching element 368 may not be turned on or off at the same time.

When the first connection switching element 366 is turned on and the second connection switching element 368 is turned off, because current flows from the first current source 365 and the first connection switching element 366 to the triangular capacitor 369, the triangular capacitor 369 may be charged. Accordingly, the first triangular voltage stage V_{TRI1} may increase.

Conversely, when the first connection switching element 366 is turned off and the second connection switching element 368 is turned on, because current flows from the triangular capacitor 369 to the second connection switching element 368 and the second current source 367, the triangular capacitor 369 may be discharged. Accordingly, the first triangular voltage V_{TRI1} may decrease.

The first logic switching element 370 may be connected between the first operating voltage stage V_{DD} and the first triangular voltage stage V_{TRI1}. The first logic switching element 370 may be connected to the first operating voltage stage V_{DD} through one end (for example, a source stage) of the first logic switching element 370. The first logic switching element 370 may be connected to the first triangular voltage stage V_{TRI1} through the other end (for example, a drain stage) of the first logic switching element 370. An input stage (for example, a gate stage) of the first logic switching element 370 may be connected to an output stage of the first voltage clamper 373.

The third current source 371 may be connected to the ground voltage stage through one end of the third current source 371.

The second logic switching element 372 may be connected between the first operating voltage stage V_{DD} and the third current source 371. The second logic switching element 372 may be connected to the third current source 371 through one end (for example, a source stage) of the second logic switching element 372. The second logic switching element 372 may be connected to the first operating voltage stage V_{DD} through the other end (for example, a drain stage) of the second logic switching element 372. An input stage (for example, a gate stage) of the second logic switching element 372 may be connected to the output stage of the first voltage clamper 373.

The first voltage clamper 373 may receive the first triangular voltage V_{TRI1} and a first peak reference voltage V_{PEAK_REF1}. The first peak reference voltage V_{PEAK_REF1} may correspond to a minimum voltage magnitude that the first triangular voltage V_{TRI1} may have. The output stage of the first voltage clamper 373 may be connected to the input stage of the first logic switching element 370 and the input stage of the second logic switching element 372. Accordingly, the first voltage clamper 373 may turn on the first logic switching element 370 and the second logic switching element 372 based on the first triangular voltage V_{TRI1} and the first peak reference voltage V_{PEAK_REF1}.

The second inverter 374 may invert a voltage on a node connected between the second logic switching element 372 and the third current source 371.

The third inverter 375 may invert the output voltage of the second inverter 374 to output the inverted output voltage as the first logic voltage V_{L1}.

The first voltage clamper 373 may turn on the first logic switching element 370 and the second logic switching element 372 when the first triangular voltage V_{TRI1} decreases and becomes equal to the first peak reference voltage V_{PEAK_REF1}. When the first logic switching element 370 and the second logic switching element 372 are turned on, the voltage on the node connected between the second logic switching element 372 and the third current source 371 may have a value corresponding to logic 1. Accordingly, the output of the second inverter 374 may have a value corresponding to logic 0, and the first logic voltage V_{L1} that is the output from the third inverter 375 may have a value corresponding to logic 1. Because the first logic voltage V_{L1} has a value corresponding to logic 1, a rising edge may occur in the first logic voltage V_{L1}. In response to the rising edge of the first logic voltage V_{L1}, the first switching control voltage V_{SW_CON1} may have a value of logic 0. Accordingly, because the first connection switching element 366 is turned on, and current flows from the first current source 365 and the first connection switching element 366 to the triangular capacitor 369, the triangular capacitor 369 may be charged. Accordingly, the first triangular voltage V_{TRI1} may stop decreasing and start increasing.

The third logic switching element 376 may be connected between the second operating voltage stage V_{SS} and the first triangular voltage stage V_{TRI1}. The third logic switching element 376 may be connected to the second operating voltage stage V_{SS} through one end (for example, a source stage) of the third logic switching element 376. The third logic switching element 376 may be connected to the first triangular voltage stage V_{TRI1} through the other end (for example, a drain stage) of the third logic switching element 376. An input stage (for example, a gate stage) of the third logic switching element 376 may be connected to an output stage of the second voltage clamper 379.

The fourth current source 377 may be connected to the first operating voltage stage V_{DD} through one end of the fourth current source 377.

The fourth logic switching element 378 may be connected between the second operating voltage stage V_{SS} and the fourth current source 377. The fourth logic switching element 378 may be connected to the fourth current source 377 through one end (for example, a source stage) of the fourth logic switching element 378. The fourth logic switching element 378 may be connected to the second operating voltage stage V_{SS} through the other end (for example, a drain stage) of the fourth logic switching element 378. An input stage (for example, a gate stage) of the fourth logic switching element 378 may be connected to the output stage of the second voltage clamper 379.

The second voltage clamper 379 may receive the first triangular voltage V_{TRI1} and a second peak reference voltage V_{PEAK_REF2}. The second peak reference voltage V_{PEAK_REF2} may correspond to a maximum voltage magnitude that the first triangular voltage V_{TRI1} may have. The output stage of the second voltage clamper 379 may be connected to the input stage of the third logic switching element 376 and the input stage of the fourth logic switching element 378. Accordingly, the second voltage clamper 379 may turn on the third logic switching element 376 and the fourth logic switching element 378 based on the first triangular voltage V_{TRI1} and the second peak reference voltage V_{PEAK_REF2}.

The fourth inverter 380 may invert a voltage on a node connected between the fourth logic switching element 378 and the fourth current source 377 to output the inverted voltage as the second logic voltage V_{L2}.

The second voltage clamper 379 may turn on the third logic switching element 376 and the fourth logic switching element 378 when the first triangular voltage V_{TRI1} increases and becomes equal to the second peak reference voltage V_{PEAK_REF2}. When the third logic switching element 376 and the fourth logic switching element 378 are turned on, the voltage on the node connected between the fourth logic switching element 378 and the fourth current source 377 may have a value corresponding to logic 0. Accordingly, the output of the fourth inverter 380 may have a value corresponding to logic 1. Because the second logic voltage V_{L2} has a value corresponding to logic 1, a rising edge may occur in the second logic voltage V_{L2}. In response to the rising edge of the second logic voltage V_{L2}, the second switching control voltage V_{SW_CON2} may have a value of logic 1. Accordingly, because the second connection switching element 368 is turned on, and current flows from the triangular capacitor 369 to the second connection switching element 368 and the second current source 367, the triangular capacitor 369 may be discharged. Accordingly, the first triangular voltage V_{TRI1} may stop increasing and start decreasing.

Returning to FIG. 6, the second triangular voltage generator 333 may receive the clock switching voltage V_{SW_CLK}, the first phase clock voltage V_{CLK_P1}, and the second phase clock voltage V_{CLK_P2}. The second triangular voltage generator 333 may generate a second triangular voltage V_{TRI2} having a complementary phase to the first triangular voltage V_{TRI1} based on the clock switching voltage V_{SW_CLK}, the first phase clock voltage V_{CLK_P1}, and the second phase clock voltage V_{CLK_P2}. The second triangular voltage generator 333 has the same structure as the first triangular voltage generator 332, but may operate by applying the first phase clock voltage V_{CLK_P1} and the second phase clock voltage V_{CLK_P2} in reverse.

Returning to FIG. 4, the switching voltage generating circuit 340 may generate one or more switching voltages based on the first triangular voltage V_{TRI1}, the second triangular voltage V_{TRI2}, and the error voltage V_{ERR}. In the embodiment of FIG. 4, in order to generate the switching voltage applied to the DC-DC converter 110 of FIG. 2, the switching voltage generating circuit 340 may generate first to fourth switching voltages V_{SW1} to V_{SW4}. For convenience of explanation, the following description will focus on an embodiment in which the switching voltage generating circuit 340 generates the first to fourth switching voltages V_{SW1} to V_{SW4}.

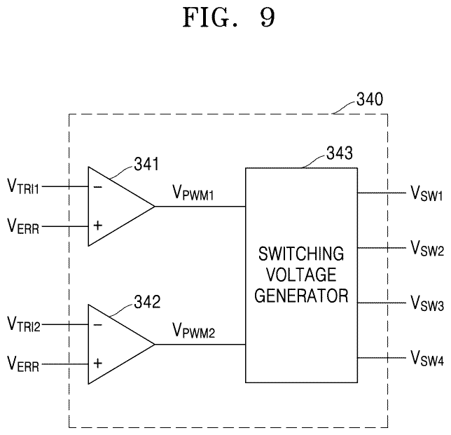

A more specific structure and operation of the switching voltage generating circuit 340 may be described in more detail with reference to FIG. 9.

FIG. 9 is a diagram illustrating the switching voltage generating circuit 340 included in the switching voltage generating device 300 according to an embodiment.

Referring to FIG. 9, the switching voltage generating circuit 340 according to an embodiment may include a first pulse width modulation (PWM) comparator 341, a second PWM comparator 342, and a switching voltage generator 343.

The first PWM comparator 341 may receive the first triangular voltage V_{TRI1} and the error voltage V_{ERR}. The first PWM comparator 341 may compare the first triangular voltage V_{TRI1} with the error voltage V_{ERR} to generate a first PWM voltage V_{PWM1}. For example, the first PWM comparator 341 may generate the first PWM voltage V_{PWM1} having a value of logic 0 when the first triangular voltage V_{TRI1} is greater than the error voltage V_{ERR}. Conversely, the first PWM comparator 341 may generate the first PWM voltage V_{PWM1} having a value of logic 1 when the first triangular voltage V_{TRI1} is less than the error voltage V_{ERR}.

The second PWM comparator 342 may receive the second triangular voltage V_{TRI2} and the error voltage V_{ERR}. The second PWM comparator 342 may compare the second triangular voltage V_{TRI2} with the error voltage V_{ERR} to generate a second PWM voltage V_{PWM2}. For example, the second PWM comparator 342 may generate the second PWM voltage V_{PWM2} having a value of logic 0 when the second triangular voltage V_{TRI2} is greater than the error voltage V_{ERR}. Conversely, the second PWM comparator 342 may generate the second PWM voltage V_{PWM2} having a value of logic 1 when the second triangular voltage V_{TRI2} is less than the error voltage V_{ERR}.

The switching voltage generator 343 may receive the first PWM voltage V_{PWM1} and the second PWM voltage V_{PWM2}. The switching voltage generator 343 may generate the first to fourth switching voltages V_{SW1} to V_{SW4} based on the first PWM voltage V_{PWM1} and the second PWM voltage V_{PWM2}.

The switching voltage generator 343 may generate the first switching voltage V_{SW1} and the second switching voltage V_{SW2} based on the first PWM voltage V_{PWM1}. The switching voltage generator 343 may generate the first switching voltage V_{SW1} identical to the first PWM voltage V_{PWM1}. The switching voltage generator 343 may invert the first PWM voltage V_{PWM1} to generate the second switching voltage V_{SW2}.

The switching voltage generator 343 may generate the third switching voltage V_{SW3} and the fourth switching voltage V_{SW4} based on the second PWM voltage V_{PWM2}. The switching voltage generator 343 may generate the third switching voltage V_{SW3} identical to the second PWM voltage V_{PWM2}. The switching voltage generator 343 may invert the second PWM voltage V_{PWM2} to generate the fourth switching voltage V_{SW4}.

Returning to FIG. 4 again, the switching voltage generating device 300 according to an embodiment may increase the cycle of the clock voltage V_{CLK} by reducing the frequency of the clock voltage V_{CLK} without additionally reducing the time during which the first PWM voltage V_{PWM1} and the second PWM voltage V_{PWM2} have a value of logic 1, although the magnitude of the error voltage V_{ERR} is the magnitude of the first fold reference voltage V_{FOLD_REF1} or less. Accordingly, the switching voltage generating device 300 may increase the cycle of the first PWM voltage V_{PWM1} and the second PWM voltage V_{PWM2} and may reduce the duty ratio of the first to fourth switching voltages V_{SW1} to V_{SW4} to generate a switching voltage having a wider range of duty ratio.

In addition, the switching voltage generating device 300 according to an embodiment may increase the cycle of the clock voltage V_{CLK} by reducing the frequency of the clock voltage V_{CLK} without additionally reducing the time during which the first PWM voltage V_{PWM1} and the second PWM voltage V_{PWM2} have a value of logic 1, although the magnitude of the error voltage V_{ERR} is the magnitude of the second fold reference voltage V_{FOLD_REF2} or more. Accordingly, the switching voltage generating device 300 may increase the cycle of the first PWM voltage V_{PWM1} and the second PWM voltage V_{PWM2} and may reduce the duty ratio of the first to fourth switching voltages V_{SW1} to V_{SW4} to generate a switching voltage having a wider range of duty ratio.

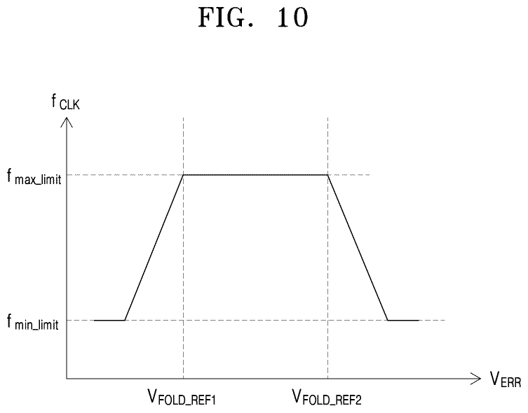

FIG. 10 is a timing diagram illustrating a relationship between the error voltage of the switching voltage generating device and a frequency of the clock voltage according to an embodiment.

Referring to FIG. 10, in an embodiment, a graph illustrating a relationship between the error voltage V_{ERR} of the switching voltage generating device 300 and a clock frequency f_{CLK} that is the frequency of the clock voltage V_{CLK} may be confirmed.

First, when the error voltage V_{ERR} is the first fold reference voltage V_{FOLD_REF1} or more and the second fold reference voltage V_{FOLD_REF2} or less, because the result of subtracting the error voltage V_{ERR} from the first fold reference voltage V_{FOLD_REF1} is negative, the first error current I_{ERR1} may become 0 A, and because the result of subtracting the second fold reference voltage V_{FOLD_REF2} from the error voltage V_{ERR} is negative, the second error current I_{ERR2} may become 0 A. Accordingly, because the current input to the first oscillator 323 becomes 0 A, the first oscillator 323 may output the first frequency voltage V_{FREQ1} having the maximum limit frequency V_{max_limit}. At this time, because the first frequency voltage V_{FREQ1} has a higher frequency than the second frequency voltage V_{FREQ2} having a frequency corresponding to the minimum limit frequency V_{min_limit}, the logic element 325 may output the first frequency voltage V_{FREQ1} as the clock voltage V_{CLK}. Therefore, the clock frequency f_{CLK} may be the maximum limit frequency V_{max_limit}.

Then, when the error voltage V_{ERR} decreases to the first fold reference voltage V_{FOLD_REF1} or less, because the result of subtracting the error voltage V_{ERR} from the first fold reference voltage V_{FOLD_REF1} increases, the first error current I_{ERR1} may increase in proportion to the difference between the error voltage V_{ERR} and the first fold reference voltage V_{FOLD_REF1}. At this time, because the result of subtracting the second fold reference voltage V_{FOLD_REF2} from the error voltage V_{ERR} is negative, the second error current I_{ERR2} may become 0 A. Accordingly, because the current input to the first oscillator 323 increases in proportion to the difference between the error voltage V_{ERR} and the first fold reference voltage V_{FOLD_REF1}, the frequency of the first frequency voltage V_{FREQ1} of the first oscillator 323 may decrease from the maximum limit frequency V_{max_limit}. At this time, although the frequency of the first frequency voltage V_{FREQ1} decreases, when the frequency of the first frequency voltage V_{FREQ1} is greater than the minimum limit frequency V_{min_limit}, because the logic element 325 outputs the first frequency voltage V_{FREQ1} as the clock voltage V_{CLK}, the clock frequency f_{CLK} may have a decreasing form. Then, when the frequency of the first frequency voltage V_{FREQ1} decreases and becomes less than the minimum limit frequency V_{min_limit}, because the logic element 325 outputs the second frequency voltage V_{FREQ2} as the clock voltage V_{CLK}, the clock frequency f_{CLK} may be fixed to the minimum limit frequency V_{min_limit}.

Finally, when the error voltage V_{ERR} increases to the second fold reference voltage V_{FOLD_REF2} or more, because the result of subtracting the second fold reference voltage V_{FOLD_REF2} from the error voltage V_{ERR} increases, the second error current I_{ERR2} may increase in proportion to the difference between the second fold reference voltage V_{FOLD_REF2} and the error voltage V_{ERR}. At this time, because the result of subtracting the error voltage V_{ERR} from the first fold reference voltage V_{FOLD_REF1} is negative, the first error current I_{ERR1} may become 0 A. Accordingly, because the current input to the first oscillator 323 increases in proportion to the difference between the second fold reference voltage V_{FOLD_REF2} and the error voltage V_{ERR}, the frequency of the first frequency voltage V_{FREQ1} of the first oscillator 323 may decrease from the maximum limit frequency V_{max_limit}. At this time, although the frequency of the first frequency voltage V_{FREQ1} decreases, when the frequency of the first frequency voltage V_{FREQ1} is greater than the minimum limit frequency V_{min_limit}, because the logic element 325 outputs the first frequency voltage V_{FREQ1} as the clock voltage V_{CLK}, the clock frequency f_{CLK} may have a decreasing form. Then, when the frequency of the first frequency voltage V_{FREQ1} decreases and becomes less than the minimum limit frequency V_{min_limit}, because the logic element 325 outputs the second frequency voltage V_{FREQ2} as the clock voltage V_{CLK}, the clock frequency f_{CLK} may be fixed to the minimum limit frequency V_{min_limit}.

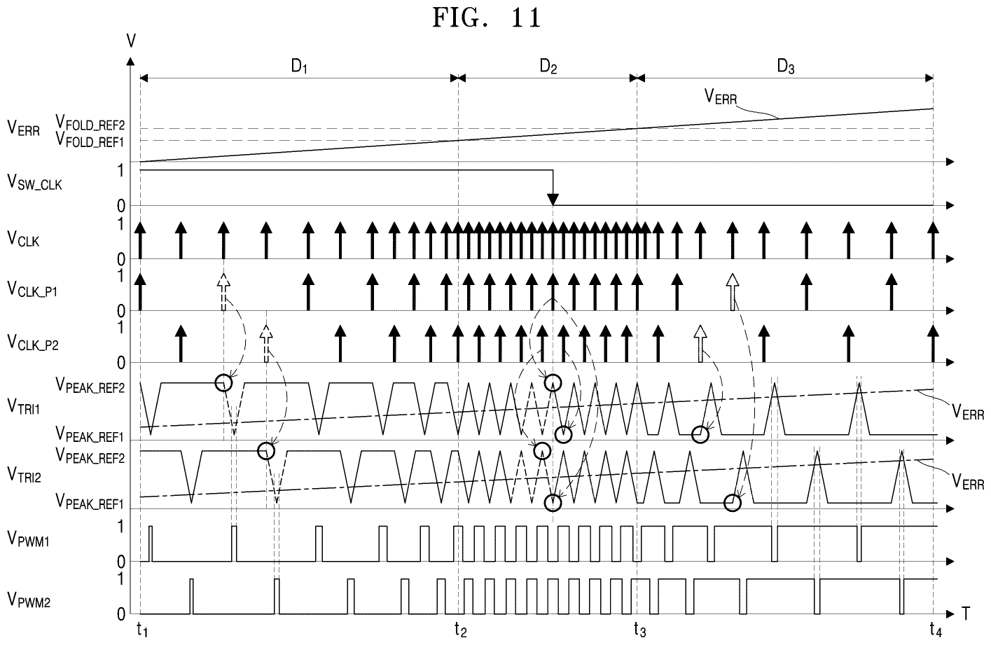

FIG. 11 is a timing diagram illustrating a relationship between voltages generated from the switching voltage generating device according to an embodiment.

Referring to FIG. 11, changes in the error voltage V_{ERR}, the clock switching voltage V_{SW_CLK}, the clock voltage V_{CLK}, the first phase clock voltage V_{CLK_P1}, the second phase clock voltage V_{CLK_P2}, the first triangular voltage V_{TRI1}, the second triangular voltage V_{TRI2}, the first PWM voltage V_{PWM1}, and the second PWM voltage V_{PWM2} may be confirmed in a first section D₁, a second section D₂, and a third section D₃. In the timing diagram of FIG. 11, the horizontal axis may represent time T and the vertical axis may represent voltage V.

First, in the first section D₁, the error voltage V_{ERR} may have an increasing form while being less than the first fold reference voltage V_{FOLD_REF1} and the second fold reference voltage V_{FOLD_REF2}.

Because the error voltage V_{ERR} is less than the switching reference voltage V_{SW_REF} at a voltage level between the first fold reference voltage V_{FOLD_REF1} and the second fold reference voltage V_{FOLD_REF2}, the clock switching voltage V_{SW_CLK} may have a value of logic 0.

Because the error voltage V_{ERR} increases from being a voltage less than the first fold reference voltage V_{FOLD_REF1} to the first fold reference voltage V_{FOLD_REF1}, the frequency of the clock voltage V_{CLK} increases so that the cycle of the clock voltage V_{CLK} may decrease. Accordingly, a distance between rising edges of the clock voltage V_{CLK} in the first section D₁ may be reduced.

Because the clock voltage V_{CLK} is alternately output as the first phase clock voltage V_{CLK_P1} and the second phase clock voltage V_{CLK_P2}, the first phase clock voltage V_{CLK_P1} and the second phase clock voltage V_{CLK_P2} may alternately have the same rising edge as the clock voltage V_{CLK}.

The first triangular voltage V_{TRI1} may decrease in response to the rising edge of the first phase clock voltage V_{CLK_P1}. At this time, the first triangular voltage V_{TRI1} decreases in response to the rising edge of the first phase clock voltage V_{CLK_P1}, and when the first triangular voltage V_{TRI1} becomes equal to the first peak reference voltage V_{PEAK_REF1}, the first voltage clamper 373 operates so that a rising edge occurs in the first logic voltage V_{L1}, and that the first triangular voltage V_{TRI1} may stop decreasing and then increase. At this time, the first triangular voltage V_{TRI1} may increase to the second peak reference voltage V_{PEAK_REF2}, may be maintained at the second peak reference voltage V_{PEAK_REF2}, and then may decrease again in response to the rising edge of the first phase clock voltage V_{CLK_P1} from a state of being the second peak reference voltage V_{PEAK_REF2}.

The first phase clock voltage V_{CLK_P1} and the second phase clock voltage V_{CLK_P2} may be applied in opposite directions to the second triangular voltage generator 333 generating the second triangular voltage V_{TRI2}. Therefore, the second triangular voltage V_{TRI2} may decrease in response to the rising edge of the second phase clock voltage V_{CLK_P2}. At this time, the second triangular voltage V_{TRI2} decreases in response to the rising edge of the second phase clock voltage V_{CLK_P2}, and when the second triangular voltage V_{TRI2} becomes equal to the first peak reference voltage V_{PEAK_REF1}, the first voltage clamper 373 operates so that a rising edge occurs in the first logic voltage V_{L1}, and that the second triangular voltage V_{TRI2} may stop decreasing and then increase. At this time, the second triangular voltage V_{TRI2} may increase to the second peak reference voltage V_{PEAK_REF2}, may be maintained at the second peak reference voltage V_{PEAK_REF2}, and then may decrease again in response to the rising edge of the second phase clock voltage V_{CLK_P2} from a state of being the second peak reference voltage V_{PEAK_REF2}.

The first PWM voltage V_{PWM1} may have a value of logic 1 when the first triangular voltage V_{TRI1} is less than the error voltage V_{ERR}. Conversely, the first PWM voltage V_{PWM1} may have a value of logic 0 when the first triangular voltage V_{TRI1} is greater than the error voltage V_{ERR}. At this time, because the magnitude of the error voltage V_{ERR} increases in the first section D₁ and a section in which the first triangular voltage V_{TRI1} is less than the error voltage V_{ERR} becomes longer, the time in which the first PWM voltage V_{PWM1} has a value of logic 1 in one cycle may increase. In addition, because the magnitude of the error voltage V_{ERR} increases in the first section D₁, and the cycle of the clock voltage V_{CLK} decreases, a length of one cycle of the first PWM voltage V_{PWM1} may be reduced.

The second PWM voltage V_{PWM2} may have a value of logic 1 when the second triangular voltage V_{TRI2} is less than the error voltage V_{ERR}. Conversely, the second PWM voltage V_{PWM2} may have a value of logic 0 when the second triangular voltage V_{TRI2} is greater than the error voltage V_{ERR}. At this time, because the magnitude of the error voltage V_{ERR} increases in the first section D₁ and a section in which the second triangular voltage V_{TRI2} is less than the error voltage V_{ERR} becomes longer, the time in which the second PWM voltage V_{PWM2} has a value of logic 1 in one cycle may increase. In addition, because the magnitude of the error voltage V_{ERR} increases in the first section D₁, and the cycle of the clock voltage V_{CLK} decreases, a length of one cycle of the second PWM voltage V_{PWM2} may be reduced.

Next, in the second section D₂, the error voltage V_{ERR} may have an increasing form from a stage of being greater than the first fold reference voltage V_{FOLD_REF1} and less than the second fold reference voltage V_{FOLD_REF2}.

At this time, because the error voltage V_{ERR} becomes greater than the switching reference voltage V_{SW_REF} from a state in which the error voltage V_{ERR} is less than the switching reference voltage V_{SW_REF} at a voltage level between the first fold reference voltage V_{FOLD_REF1} and the second fold reference voltage V_{FOLD_REF2}, the clock switching voltage V_{SW_CLK} may switch from logic 1 to logic 0.

Because the error voltage V_{ERR} increases from the first fold reference voltage V_{FOLD_REF1} to the second fold reference voltage V_{FOLD_REF2}, the frequency of the clock voltage V_{CLK} may be constant and the cycle of the clock voltage V_{CLK} may be constant. Accordingly, a distance between rising edges of the clock voltage V_{CLK} in the second section D₂ may be constant.

Because the clock voltage V_{CLK} is alternately output as the first phase clock voltage V_{CLK_P1} and the second phase clock voltage V_{CLK_P2}, the first phase clock voltage V_{CLK_P1} and the second phase clock voltage V_{CLK_P2} may alternately have the same rising edge as the clock voltage V_{CLK}.

Therefore, when the error voltage V_{ERR} is greater than the switching reference voltage V_{SW_REF} in the second section D₂, the first triangular voltage V_{TRI1} may decrease in response to the rising edge of the first phase clock voltage V_{CLK_P1}. At this time, the first triangular voltage V_{TRI1} decreases in response to the rising edge of the first phase clock voltage V_{CLK_P1}, and when the first triangular voltage V_{TRI1} becomes equal to the first peak reference voltage V_{PEAK_REF1}, the first voltage clamper 373 operates so that a rising edge occurs in the first logic voltage V_{L1}, and that the first triangular voltage V_{TRI1} may stop decreasing and then increase. At this time, the first triangular voltage V_{TRI1} may increase to the second peak reference voltage V_{PEAK_REF2}, and when the first triangular voltage V_{TRI1} becomes equal to the second peak reference voltage V_{PEAK_REF2}, the rising edge of the first phase clock voltage V_{CLK_P1} occurs so that the first triangular voltage V_{TRI1} may decrease again.

When the error voltage V_{ERR} is less than the switching reference voltage V_{SW_REF} in the second section D₂, the first triangular voltage V_{TRI1} may increase in response to the rising edge of the second phase clock voltage V_{CLK_P2}. At this time, the first triangular voltage V_{TRI1} increases in response to the rising edge of the second phase clock voltage V_{CLK_P2}, and when the first triangular voltage V_{TRI1} becomes equal to the second peak reference voltage V_{PEAK_REF2}, the second voltage clamper 379 operates so that a rising edge occurs in the second logic voltage V_{L2}, and that the first triangular voltage V_{TRI1} may stop increasing and decrease. At this time, the first triangular voltage V_{TRI1} may decrease to the first peak reference voltage V_{PEAK_REF1}, and when the first triangular voltage V_{TRI1} becomes equal to the first peak reference voltage V_{PEAK_REF1}, the rising edge of the second phase clock voltage V_{CLK_P2} occurs so that the first triangular voltage V_{TRI1} may increase again.

When the error voltage V_{ERR} is greater than the switching reference voltage V_{SW_REF} in the second section D₂, the second triangular voltage V_{TRI2} may decrease in response to the rising edge of the second phase clock voltage V_{CLK_P2}. At this time, the second triangular voltage V_{TRI2} decreases in response to the rising edge of the second phase clock voltage V_{CLK_P2}, and when the second triangular voltage V_{TRI2} becomes equal to the first peak reference voltage V_{PEAK_REF1}, the first voltage clamper 373 operates so that a rising edge occurs in the first logic voltage V_{L1}, and that the second triangular voltage V_{TRI2} may stop decreasing and increase. At this time, the second triangular voltage V_{TRI2} may increase to the second peak reference voltage V_{PEAK_REF2}, and when the second triangular voltage V_{TRI2} becomes equal to the second peak reference voltage V_{PEAK_REF2}, the rising edge of the first phase clock voltage V_{CLK_P1} occurs so that the second triangular voltage V_{TRI2} may decrease again.

When the error voltage V_{ERR} is less than the switching reference voltage V_{SW_REF} in the second section D₂, the second triangular voltage V_{TRI2} may increase in response to the rising edge of the first phase clock voltage V_{CLK_P1}. At this time, the second triangular voltage V_{TRI2} increases in response to the rising edge of the firsts phase clock voltage V_{CLK_P1}, and when the second triangular voltage V_{TRI2} becomes equal to the second peak reference voltage V_{PEAK_REF2}, the second voltage clamper 379 operates so that a rising edge occurs in the second logic voltage V_{L2}, and that the second triangular voltage V_{TRI2} may stop increasing and decrease. At this time, the second triangular voltage V_{TRI2} may decrease to the first peak reference voltage V_{PEAK_REF1}, and when the second triangular voltage V_{TRI2} becomes equal to the first peak reference voltage V_{PEAK_REF1}, the rising edge of the first phase clock voltage V_{CLK_P1} occurs so that the second triangular voltage V_{TRI2} may increase again.

The first PWM voltage V_{PWM1} may have a value of logic 1 when the first triangular voltage V_{TRI1} is less than the error voltage V_{ERR}. Conversely, the first PWM voltage V_{PWM1} may have a value of logic 0 when the first triangular voltage V_{TRI1} is greater than the error voltage V_{ERR}. At this time, because the magnitude of the error voltage V_{ERR} increases in the second section D₂ and a section in which the first triangular voltage V_{TRI1} is less than the error voltage V_{ERR} becomes longer, the time in which the first PWM voltage V_{PWM1} has a value of logic 1 in one cycle may increase.

The second PWM voltage V_{PWM2} may have a value of logic 1 when the second triangular voltage V_{TRI2} is less than the error voltage V_{ERR}. Conversely, the second PWM voltage V_{PWM2} may have a value of logic 0 when the second triangular voltage V_{TRI2} is greater than the error voltage V_{ERR}. At this time, because the magnitude of the error voltage V_{ERR} increases in the second section D₂ and a section in which the second triangular voltage V_{TRI2} is less than the error voltage V_{ERR} becomes longer, the time in which the second PWM voltage V_{PWM2} has a value of logic 1 in one cycle may increase.

Finally, in the third section D₃, the error voltage V_{ERR} may have an increasing form from a state of being greater than the first fold reference voltage V_{FOLD_REF1} and the second fold reference voltage V_{FOLD_REF2}.

Because the error voltage V_{ERR} is greater than the switching reference voltage V_{SW_REF} at a voltage level between the first fold reference voltage V_{FOLD_REF1} and the second fold reference voltage V_{FOLD_REF2}, the clock switching voltage V_{SW_CLK} may have a value of logic 0.

Because the error voltage V_{ERR} increases from being the second fold reference voltage V_{FOLD_REF2} and the frequency of the clock voltage V_{CLK} decreases, the cycle of the clock voltage V_{CLK} may increase. Accordingly, a distance between rising edges of the clock voltage V_{CLK} in the third section D₃ may increase.

Because the clock voltage V_{CLK} is alternately output as the first phase clock voltage V_{CLK_P1} and the second phase clock voltage V_{CLK_P2}, the first phase clock voltage V_{CLK_P1} and the second phase clock voltage V_{CLK_P2} may alternately have the same rising edge as the clock voltage V_{CLK}.

The first triangular voltage V_{TRI1} may increase in response to the rising edge of the second phase clock voltage V_{CLK_P2}. At this time, the first triangular voltage V_{TRI1} increases in response to the rising edge of the second phase clock voltage V_{CLK_P2}, and when the first triangular voltage V_{TRI1} becomes equal to the second peak reference voltage V_{PEAK_REF2}, the second voltage clamper 379 operates so that a rising edge occurs in the second logic voltage V_{L2}, and that the first triangular voltage V_{TRI1} may stop increasing and then decrease. At this time, the first triangular voltage V_{TRI1} may decrease to the first peak reference voltage V_{PEAK_REF1}, may be maintained at the first peak reference voltage V_{PEAK_REF1}, and then may increase again in response to the rising edge of the second phase clock voltage V_{CLK_P2} from a state of being the first peak reference voltage V_{PEAK_REF1}.

The second triangular voltage V_{TRI2} may increase in response to the rising edge of the first phase clock voltage V_{CLK_P1}. At this time, the second triangular voltage V_{TRI2} increases in response to the rising edge of the first phase clock voltage V_{CLK_P1}, and when the second triangular voltage V_{TRI2} becomes equal to the second peak reference voltage V_{PEAK_REF2}, the second voltage clamper 379 operates so that a rising edge occurs in the second logic voltage V_{L2}, and that the second triangular voltage V_{TRI2} may stop increasing and decrease. At this time, the second triangular voltage V_{TRI2} may decrease to the first peak reference voltage V_{PEAK_REF1}, may be maintained at the first peak reference voltage V_{PEAK_REF1}, and then may decrease again in response to the rising edge of the first phase clock voltage V_{CLK_P1} from a state of being the first peak reference voltage V_{PEAK_REF1}.

The first PWM voltage V_{PWM1} may have a value of logic 1 when the first triangular voltage V_{TRI1} is less than the error voltage V_{ERR}. Conversely, the first PWM voltage V_{PWM1} may have a value of logic 0 when the first triangular voltage V_{TRI1} is greater than the error voltage V_{ERR}. At this time, because the magnitude of the error voltage V_{ERR} increases in the third section D₃ and a section in which the first triangular voltage V_{TRI1} is less than the error voltage V_{ERR} becomes longer, the time in which the first PWM voltage V_{PWM1} has a value of logic 1 in one cycle may increase. In addition, because the magnitude of the error voltage V_{ERR} increases in the third section D₃, and the cycle of the clock voltage V_{CLK} increases, a length of one cycle of the first PWM voltage V_{PWM1} may increase.

The second PWM voltage V_{PWM2} may have a value of logic 1 when the second triangular voltage V_{TRI2} is less than the error voltage V_{ERR}. Conversely, the second PWM voltage V_{PWM2} may have a value of logic 0 when the second triangular voltage V_{TRI2} is greater than the error voltage V_{ERR}. At this time, because the magnitude of the error voltage V_{ERR} increases in the third section D₃ and a section in which the second triangular voltage V_{TRI2} is less than the error voltage V_{ERR} becomes longer, the time in which the second PWM voltage V_{PWM2} has a value of logic 1 in one cycle may increase. In addition, because the magnitude of the error voltage V_{ERR} increases in the third section D₃, and the cycle of the clock voltage V_{CLK} increases, a length of one cycle of the second PWM voltage V_{PWM2} may increase.

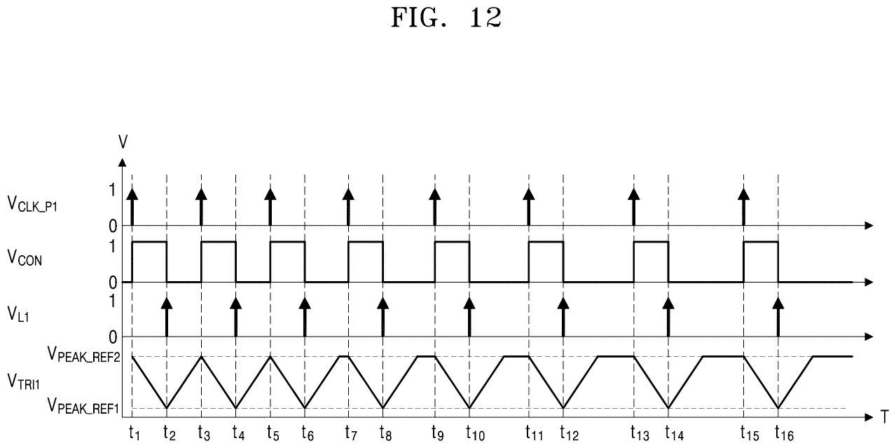

FIG. 12 is a timing diagram illustrating a relationship between voltages generated by the first triangular voltage generator of the switching voltage generating device according to an embodiment.

Referring to FIG. 12, when the clock switching voltage V_{SW_CLK} is logic 1 and the cycle of the clock voltage V_{CLK} increases, changes in the first phase clock voltage V_{CLK_P1}, the control voltage V_{CON}, the first logic voltage V_{L1}, and the first triangular voltage V_{TRI1} may be confirmed. In the timing diagram of FIG. 12, the horizontal axis may represent time T and the vertical axis may represent voltage V.

At an ith time point tᵢ (i is odd), the rising edge of the first phase clock voltage V_{CLK_P1} may occur. In response to the rising edge of the first phase clock voltage V_{CLK_P1}, the first triangular voltage V_{TRI1} may decrease.

At a jth time point tj (j is even), a rising edge of the first logic voltage V_{L1} may occur. In response to the rising edge of the first logic voltage V_{L1}, the first triangular voltage V_{TRI1} may increase.

At this time, because the cycle of the clock voltage V_{CLK} increases, a distance between the rising edges of the first phase clock voltage V_{CLK_P1} may increase. Therefore, it may be confirmed that, as time passes, a distance between the rising edges of the first phase clock voltage V_{CLK_P1}, that is, a distance between the ith time points tᵢ increases. It may also be confirmed that, as time passes, a distance between the rising edges of the first logic voltage V_{L1}, that is, a distance between the jth time points tⱼ increases.

At this time, because the rising edge of the first logic voltage V_{L1} is generated from the first voltage clamper 373, a distance between the ith time point tᵢ and the (i+1)th time point tᵢ₊₁ may be constant. For example, the distance between the ith time point tᵢ and the (i+1)th time point tᵢ₊₁ may be constant when the i is odd number.

However, because the rising edge of the first phase clock voltage V_{CLK_P1} is generated by the clock voltage V_{CLK}, and the cycle of the clock voltage V_{CLK} increases, a distance between the jth time point tⱼ and the (j+1)th time point tⱼ₊₁ may increase. At this time, although the distance between the jth time point tⱼ and the (j+1)th time point tⱼ₊₁ increases, the slope of the increase in the first triangular voltage V_{TRI1} is constant, a section in which the first triangular voltage V_{TRI1} is maintained as the second peak reference voltage V_{PEAK_REF2} may occur. The section in which the first triangular voltage V_{TRI1} is maintained as the second peak reference voltage V_{PEAK_REF2} may become longer as the cycle of the clock voltage V_{CLK} increases.

As described above, embodiments have been disclosed in the drawings and specification. Although specific terms have been used to describe embodiments in this specification, they are used only for the purpose of explaining the technical idea of the inventive concept and are not intended to limit the meaning or the scope of the inventive concept set forth in the claims. Therefore, a person having ordinary skill in the art will understand that various modifications and equivalent other embodiments are possible. Therefore, the true technical protection scope of the inventive concept should be determined by the technical idea of the appended claims.

While the inventive concept has been particularly shown and described with reference to embodiments thereof, it will be understood that various changes in form and details may be made therein without departing from the spirit and scope of the present invention as set forth in the following claims.

What is claimed is:

1. A switching voltage generating device generating one or more switching voltages input to one or more switching elements included in a voltage converting circuit, the switching voltage generating device comprising:
an amplifier configured to generate an error voltage, based on a adjusting target voltage of the voltage converting circuit and a detection voltage of the voltage converting circuit;
a clock voltage generating circuit configured to:
generate a clock voltage having a frequency corresponding to the error voltage, based on the error voltage, a first fold reference voltage, and a second fold reference voltage, and
generate a clock switching voltage based on the error voltage and a switching reference voltage;
a triangular voltage generating circuit configured to generate one or more triangular voltages having a cycle corresponding to a cycle of the clock voltage based on the clock switching voltage and the clock voltage; and
a switching voltage generating circuit configured to generate the one or more switching voltages based on the one or more triangular voltages and the error voltage.

2. The switching voltage generating device of claim 1, wherein the amplifier is configured to:
amplify a voltage difference between the adjusting target voltage and the detection voltage, and
generate the error voltage based on the amplified voltage difference.

3. The switching voltage generating device of claim 1, wherein the clock voltage generating circuit includes:
a first operational transconductance amplifier (OTA) configured to output a first error current corresponding to a difference between the error voltage and the first fold reference voltage;
a second OTA configured to output a second error current corresponding to a difference between the error voltage and the second fold reference voltage;
a first oscillator configured to output a first frequency voltage having a frequency inversely proportional to the first error current and the second error current;
a second oscillator configured to output a second frequency voltage having a frequency corresponding to a minimum limit frequency of the clock voltage; and
a logic element configured to output a voltage having a higher frequency among the first frequency voltage and the second frequency voltage as a clock voltage.

4. The switching voltage generating device of claim 1, wherein the clock voltage generating circuit includes a switching comparator configured to:
compare the error voltage with the switching reference voltage, and
generate the one or more clock switching voltages based on a result of the comparison.

5. The switching voltage generating device of claim 1, wherein the triangular voltage generating circuit includes:
a demultiplexer configured to generate a first phase clock voltage and a second phase clock voltage based on the clock voltage; and
a first triangular voltage generator configured to generate a first triangular voltage among the one or more triangular voltages based on the clock switching voltage, the first phase clock voltage, and the second phase clock voltage.

6. The switching voltage generating device of claim 5, wherein the first triangular voltage generator includes:
a first latch configured to generate a first switching control voltage, based on the first phase clock voltage and a first logic voltage;
a second latch configured to generate a second switching control voltage, based on the second phase clock voltage and a second logic voltage;
a multiplexer configured to select one of the first switching control voltage and the second switching control voltage as a control voltage based on the clock switching voltage;
a first inverter configured to invert the control voltage and output an inverted control voltage;
a first current source of which one end is connected to a first operating voltage stage;
a first connection switching element configured to turn on or off based on the inverted control voltage and connected between the other end of the first current source and a first triangular voltage stage;
a second current source of which one end is connected to a second operating voltage stage;
a second connection switching element configured to turn on or off based on the control voltage and connected between the other end of the second current source and the first triangular voltage stage;
a triangular capacitor of which one end is connected to the first triangular voltage stage and of which the other end is connected to the second operating voltage stage;
a first logic switching element connected between the first operating voltage stage and the first triangular voltage stage;
a third current source of which one end is connected to a ground voltage stage;
a second logic switching element connected between the first operating voltage stage and the third current source;
a first voltage clamper configured to turn on the first logic switching element and the second logic switching element based on the first triangular voltage and a first peak reference voltage;
a second inverter configured to invert a second voltage on a node between the second logic switching element and the third current source and output the inverted second voltage;
a third inverter configured to invert an output voltage from the second inverter and output the inverted output voltage as the first logic voltage;
a third logic switching element connected between the second operating voltage stage and the first triangular voltage;
a fourth current source of which one end is connected to the first operating voltage stage;
a fourth logic switching element connected between the second operating voltage stage and the fourth current source;
a second voltage clamper configured to turn on the third logic switching element and the fourth logic switching element based on the first triangular voltage and a second peak reference voltage greater than the first peak reference voltage; and
a fourth inverter configured to invert a fourth voltage on a node between the fourth logic switching element and the fourth current source and output the inverted fourth voltage as the second logic voltage, and
wherein the second operating voltage stage is the ground voltage stage.

7. The switching voltage generating device of claim 5, wherein the triangular voltage generating circuit further includes:
a second triangular voltage generator configured to generate a second triangular voltage among the one or more triangular voltages having a phase complementary to the first triangular voltage based on the first phase clock voltage and the second phase clock voltage.

8. The switching voltage generating device of claim 1, wherein the switching voltage generating circuit includes:
a first pulse width modulation (PWM) comparator configured to generate a first PWM voltage by comparing a first triangular voltage among the one or more triangular voltages with the error voltage; and
a switching voltage generator configured to generate a first switching voltage and a second switching voltage among the one or more switching voltages based on the first PWM voltage.

9. The switching voltage generating device of claim 8, wherein the switching voltage generating circuit further includes:
a second PWM comparator configured to generate a second PWM voltage by comparing a second triangular voltage among the one or more triangular voltages with the error voltage, and
wherein the switching voltage generator is configured to generate a third switching voltage and a fourth switching voltage among the one or more switching voltages based on the second PWM voltage.

10. The switching voltage generating device of claim 1, further comprising:
a filter circuit including a filter resistor having one end connected to an output terminal of the amplifier, and a filter capacitor connected between the other end of the filter resistor and a ground voltage stage, and the filter circuit configured to filter the error voltage.

11. A voltage converting device comprising:
a voltage converting circuit configured to convert an input voltage to generate a system voltage; and
a switching voltage generating device configured to generate one or more switching voltages input to one or more switching elements included in the voltage converting circuit,
wherein the switching voltage generating device comprises:
an amplifier configured to generate an error voltage, based on a adjusting target voltage of the voltage converting circuit and a detection voltage of the voltage converting circuit;
a clock voltage generating circuit configured to generate a clock voltage having a frequency corresponding to the error voltage, based on the error voltage, a first fold reference voltage, and a second fold reference voltage, and to generate a clock switching voltage based on the error voltage and a switching reference voltage;
a triangular voltage generating circuit configured to generate one or more triangular voltages having a cycle corresponding to a cycle of the clock voltage based on the clock switching voltage and the clock voltage; and
a switching voltage generating circuit configured to generate the one or more switching voltages based on the one or more triangular voltages and the error voltage.

12. The voltage converting device of claim 11, wherein the amplifier is configured to:
amplify a voltage difference between the adjusting target voltage and the detection voltage, and
generate the error voltage based on the amplified voltage difference.

13. The voltage converting device of claim 11, wherein the clock voltage generating circuit includes:
a first operational transconductance amplifier (OTA) configured to output a first error current corresponding to a difference between the error voltage and the first fold reference voltage;
a second OTA configured to output a second error current corresponding to a difference between the error voltage and the second fold reference voltage;
a first oscillator configured to output a first frequency voltage having a frequency inversely proportional to the first error current and the second error current;
a second oscillator configured to output a second frequency voltage having a frequency corresponding to a minimum limit frequency of the clock voltage;
a logic element configured to output a voltage having a higher frequency among the first frequency voltage and the second frequency voltage as a clock voltage; and
a switching comparator configured to compare the error voltage with the switching reference voltage to generate the clock switching voltage.

14. The voltage converting device of claim 11, wherein the triangular voltage generating circuit includes:
a demultiplexer configured to generate a first phase clock voltage and a second phase clock voltage based on the clock voltage;
a first triangular voltage generator configured to generate a first triangular voltage among the one or more triangular voltages based on the clock switching voltage, the first phase clock voltage, and the second phase clock voltage; and
a second triangular voltage generator configured to generate a second triangular voltage among the one or more triangular voltages having a phase complementary to the first triangular voltage based on the first phase clock voltage and the second phase clock voltage.

15. The voltage converting device of claim 11, wherein the switching voltage generating circuit includes:
a first pulse width modulation (PWM) comparator configured to generate a first PWM voltage by comparing a first triangular voltage among the one or more triangular voltages with the error voltage;
a second PWM comparator configured to generate a second PWM voltage by comparing a second triangular voltage among the one or more triangular voltages with the error voltage; and
a switching voltage generator configured to:
generate a first switching voltage and a second switching voltage among the one or more switching voltages based on the first PWM voltage, and
generate a third switching voltage and a fourth switching voltage among the one or more switching voltages based on the second PWM voltage.

16. The voltage converting device of claim 11, wherein the voltage converting circuit includes:
a supply switching element configured to control supply of the input voltage;
a bypass capacitor connected between the supply switching element and a ground voltage stage;
a DC-DC converter connected between the supply switching element and the ground voltage stage and configured to output the system voltage;
a system current source connected between a system voltage stage and the ground voltage stage;
a system capacitor connected between the system voltage stage and the ground voltage stage;
a battery;
a charge switching element configured to control connection between the battery and the system voltage stage; and
a battery capacitor connected between one end of the battery and the ground voltage stage.

17. The voltage converting device of claim 16, further comprising:
a loop selecting circuit configured to determine the adjusting target voltage based on a supply current passing through the supply switching element, a bypass voltage on a node connected between the bypass capacitor and the DC-DC converter, the system voltage, a battery voltage on a node connected between the charge switching element and the battery, and a battery current supplied to the battery.

18. The voltage converting device of claim 16, further comprising:
a current-to-voltage converter configured to output the detection voltage based on a current output from the DC-DC converter.

19. A switching voltage generating device generating a switching voltage input to a switching element included in a voltage converting circuit, the switching voltage generating device comprising:
an amplifier configured to generate an error voltage, based on a adjusting target voltage of the voltage converting circuit and a detection voltage of the voltage converting circuit;
a clock voltage generating circuit configured to generate a clock voltage having a frequency corresponding to the error voltage;
a triangular voltage generating circuit configured to generate one or more triangular voltages having a cycle corresponding to a cycle of the clock voltage; and
a switching voltage generating circuit configured to generate the switching voltage based on the one or more triangular voltages and the error voltage.

20. The switching voltage generating device of claim 19, wherein the clock voltage generating circuit is further configured to generate a clock switching voltage, based on the error voltage and a switching reference voltage, and
wherein the triangular voltage generating circuit configured to generate the one or more triangular voltages based on the clock switching voltage and the clock voltage.
